(19) United States
(12) Patent Application Publication
(10) Pub. No.: US 2026/0182208 A1
(43) Pub. Date: Jun. 25, 2026

(54) DISPLAY APPARATUS

(71) Applicant: Wuhan Tianma Microelectronics Co., Ltd. Shanghai Branch, Shanghai (CN)

(72) Inventor: Wei SHI, Shanghai (CN)

(73) Assignee: Wuhan Tianma Microelectronics Co., Ltd. Shanghai Branch, Shanghai (CN)

(21) Appl. No.: 19/241,347

(22) Filed: Jun. 17, 2025

(30) Foreign Application Priority Data
Dec. 23, 2024 (CN) 202411914723.2

(51) Int. Cl. H10K 59/80; H10H 29/853; H10H 29/854

(52) U.S. Cl. CPC H10K 59/8722; H10H 29/853; H10H 29/854; H10K 59/873

(57) ABSTRACT

The present application discloses a display apparatus comprising: a frame body having an accommodation groove; a display panel disposed in the accommodation groove and comprising a display area and a non-display area adjacent to the display area, wherein the display panel comprises an encapsulation adhesive disposed in the non-display area, and the display panel further comprises a light-emission surface and a back surface; a first adhesive layer provided between the back surface and the frame body, wherein in a light-emission direction of the display panel, the first adhesive layer at least partially overlap the encapsulation adhesive; and a second adhesive layer at least partially located between the first adhesive layer and the frame body in the light-emission direction of the display panel, an elastic modulus of a material of the second adhesive layer being greater than an elastic modulus of a material of the first adhesive layer.

### CROSS REFERENCE TO RELATED APPLICATION

The present application claims priority to Chinese Patent Application No. 202411914723.2 filed on Dec. 23, 2024, which is incorporated herein by reference in its entirety.

### TECHNICAL FIELD

The present application relates to the technical field of electronic products, and in particular to display apparatus.

### BACKGROUND

With the progress in science and technology, smart phones, tablet computers and other digital display devices are widely used, and display screens are indispensable interpersonal communication interfaces in these digital display devices. An organic light emitting diode (OLED) display apparatus has advantages of self-luminescence, energy-saving and consumption reduction, bendibility, and flexibility. The display apparatus for displaying does not need back light, and has characteristics of a fast response and a desired display effect. It has attracted the attention of users and is widely used in smart phones, tablet computers and other terminal products.

### SUMMARY

In a first aspect, embodiments of the present application provide a display apparatus comprising: a frame body having an accommodation groove; a display panel disposed in the accommodation groove and comprising a display area and a non-display area adjacent to the display area, wherein the display panel comprises an encapsulation adhesive disposed in the non-display area, and the display panel further comprises a light-emission surface and a back surface opposite to the light-emission surface; a first adhesive layer provided between the back surface of the display panel and the frame body, wherein in a light-emission direction of the display panel, the first adhesive layer at least partially overlap the encapsulation adhesive; and a second adhesive layer at least partially located between the first adhesive layer and the frame body in the light-emission direction of the display panel, an elastic modulus of a material of the second adhesive layer being greater than an elastic modulus of a material of the first adhesive layer.

### BRIEF DESCRIPTION OF THE DRAWINGS

Drawings necessary for explaining embodiments of the present application are described briefly below to illustrate technical solutions of embodiments of the present application more clearly. Obviously, the drawings described below are merely some embodiments of the present application. Other figures can be obtained by those with ordinary skill in the art from the drawings without any inventive effort.

FIG. 1 shows a schematic structural diagram of a display apparatus provided in an embodiment of the present application;

FIG. 2 shows a schematic cross-sectional view at A-A in FIG. 1 according to an embodiment of the present application;

FIG. 3 shows a schematic cross-sectional view at A-A in FIG. 1 according to another embodiment of the present application;

FIG. 4 shows a schematic cross-sectional view at A-Ain FIG. 1 according to still another embodiment of the present application;

FIG. 5 shows a schematic cross-sectional view at A-Ain FIG. 1 according to still another embodiment of the present application;

FIG. 6 shows a schematic cross-sectional view at A-Ain FIG. 1 according to still another embodiment of the present application;

FIG. 7 shows a schematic cross-sectional view at A-Ain FIG. 1 according to still another embodiment of the present application;

FIG. 8 shows a schematic cross-sectional view at A-Ain FIG. 1 according to still another embodiment of the present application;

FIG. 9 shows a schematic structural diagram of a first adhesive layer provided in an embodiment of the present application; and

FIG. 10 shows a schematic structural diagram of a first adhesive layer provided in another embodiment of the present application.

### DETAILED DESCRIPTION

Features and exemplary embodiments of various aspects of the present application will be described in detail below. Numerous specific details are set forth in the following detailed description to provide a thorough understanding of the present invention. However, it will be apparent to a person skilled in the art that the present invention may be practiced without some of these specific details. The following description of the embodiments is merely intended to provide a better understanding of the present invention by illustrating examples of the present invention.

It should be noted that, in the present disclosure, the relational terms, such as first and second, are used merely to distinguish one entity or operation from another entity or operation, without necessarily requiring or implying any actual such relationships or orders for these entities or operations. Moreover, the terms “comprise”, “include”, or any other variants thereof, are intended to represent a non-exclusive inclusion, such that a process, method, article or device including a series of elements includes not only those elements, but also other elements that are not explicitly listed or elements inherent to such a process, method, article or device. Without more constraints, the elements following an expression “comprise/include . . . ” do not exclude the existence of additional identical elements in the process, method, article or device that includes the elements.

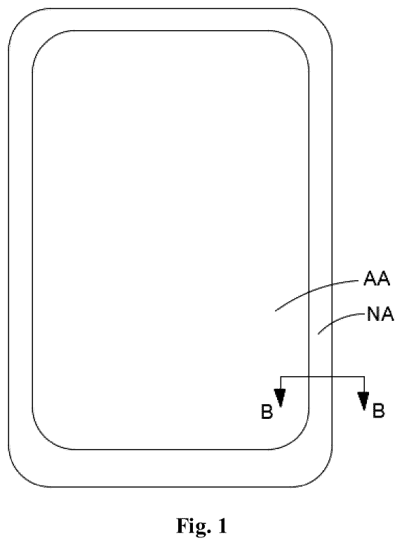

For a better understanding of the present application, a detailed description of the display apparatus according to the embodiments of the present application will be given below with reference to FIGS. 1 to 10.

The inventors found that, in the existing display apparatus, because the frame width limitation of the display apparatus, the inner edge of the encapsulation adhesive coincides with the inner edge of the adhesive layer located between the display panel and the frame body, the inner side of the encapsulation adhesive is a stress concentration point, and the display panel is easily damaged under a force at the corresponding position.

To solve the above-mentioned problems, the display apparatus provided in embodiments of the present application can limit the elastic modulus of a material of a first adhesive layer to be less than the elastic modulus of the material of a second adhesive layer, therefore the first adhesive layer is easily deformed under a force, and the stress is rapidly transmitted, so that the first adhesive layer plays the role of releasing the stress, the stress concentration is avoided, and the mechanical strength is enhanced, while the rigidity of the second adhesive layer with a high elastic modulus is relatively good, and the second adhesive layer is at least partially located between the first adhesive layer and the frame body to ensure the overall airtightness requirements of the display apparatus and to improve the reliability and service performance of the display apparatus.

Referring to FIGS. 1 to 2, FIG. 1 shows a schematic structural diagram of a display apparatus provided in an embodiment of the present application; and FIG. 2 shows a schematic cross-sectional view at A-A in FIG. 1 provided in an embodiment of the present application.

Embodiments of the present application provide a display apparatus, comprising: a frame body 1 having an accommodation groove; a display panel 2 disposed in the accommodation groove and provided with a display area AA and a non-display area NA adjacent to the display area AA, an encapsulation adhesive 21 is located in the non-display area NA, and the display panel 2 further comprises a light-emission surface and a back surface opposite to the light-emission surface; a first adhesive layer 3 provided between the back surface of the display panel 2 and the frame body 1, and in a light-emission direction Y of the display panel 2, the first adhesive layer 3 at least partially overlap the encapsulation adhesive 21; and a second adhesive layer 4 at least partially located between the first adhesive layer 3 and the frame body 1 in the light-emission direction Y of the display panel 2, and an elastic modulus of a material of the second adhesive layer 4 being greater than an elastic modulus of a material of the first adhesive layer 3.

The display apparatus provided in embodiments of the present application comprises a frame body 1, a display panel 2, a first adhesive layer 3, and a second adhesive layer 4. The first adhesive layer 3 is disposed between the back surface of the display panel 2 and the frame body 1; the elastic modulus of the material of the first adhesive layer 3 is less than the elastic modulus of the material of the second adhesive layer 4, so that the first adhesive layer 3 is easily deformed under a force, and the stress is rapidly transmitted. Therefore the first adhesive layer 3 can play a role in releasing the stress to avoid the stress concentration, improve the mechanical strength test fragment rate caused by the stress concentration at the boundary of the encapsulation adhesive 21, and enhance the mechanical strength; the rigidity of the second adhesive layer 4 with a high elastic modulus is relatively good, and the second adhesive layer 4 is at least partially located between the first adhesive layer 3 and the frame body 1 to ensure the overall airtightness requirements of the display apparatus and improve the reliability and service performance of the display apparatus.

In the present embodiment, the frame body 1 is for accommodating and fixing the display panel 2. Optionally, the frame body 1 comprises a bottom plate 11 and a side plate 12 connected to the bottom plate 11, and the bottom plate 11 and the side plate 12 enclose and form a accommodation groove.

The frame body 1 may have an integrated structure to facilitate the formation, and the structure strength of the integrated structure is relatively high. For example, the frame body 1 may be integrally formed by a die-casting process, i.e., the bottom plate 11 and the side plate 12 are integrally connected, or the frame body 1 may be manufactured and formed by a stamping process. Alternatively, the frame body 1 may have a discrete structure, i.e., the bottom plate 11 and the side plate 12 can be independently manufactured and formed.

The display panel 2 may be an OLED display panel 2, a quantum dot light emitting diodes (QLED) display panel 2, or a Micro-OLED or Micro-LED display panel 2.

Optionally, the encapsulation adhesive 21 may be Frit (glass sealant). The material of the first adhesive layer 3 comprises a one-component epoxy resin adhesive; and/or the material of the second adhesive layer 4 comprises a single-component epoxy adhesive, i.e., the first adhesive layer 3 and the second adhesive layer 4 can be made of the same material, but the elastic modulus of the material of the second adhesive layer 4 is greater than that of the material of the first adhesive layer 3 by controlling factors such as the process, or the first adhesive layer 3 and the second adhesive layer 4 can be made of different materials, as long as the adhesive property and the elastic modulus requirements are ensured.

It should be noted that, in the present embodiment, in the light-emission direction Y of the display panel 2, the first adhesive layer 3 and the encapsulation adhesive 21 at least partially overlap, which means that the first adhesive layer 3 is at least partially located below the encapsulation adhesive 21 to absorb and release the stress of the portion, corresponding to the encapsulation adhesive 21, of the display panel 2, i.e., a stress release channel is provided to reduce the force applied to the weak position (the inner side of the encapsulation adhesive 21) and improve the overall strength.

Optionally, the first adhesive layer 3 and the second adhesive layer 4 each can be formed by multi-stage injection molding. For example, the low injection pressure overmolding (LIPO) process can be adopted, the full process (low-pressure, adhesive, injection, and demolding) of the LIPO is as follows: at a relatively low temperature (many materials of screens cannot withstand high temperature), a special glue is filled into the sol cylinder of an injection molding equipment at a low pressure to melt; after melted, the glue has well fluidity and can flow into a small mold space at a small pressure; and after the glue is cooled and solidified, demolding can be carried out to complete the formation.

Optionally, in some embodiments, a ratio between the elastic modulus of the material of the second adhesive layer 4 and the elastic modulus of the material of the first adhesive layer 3 is greater than or equal to 2:1. For example, the ratio between the elastic modulus of the material of the second adhesive layer 4 and the elastic modulus of the material of the first adhesive layer 3 may be equal to 2:1, 3:1, or 4:1, so that the stress absorption effect of the first adhesive layer 3 and the rigidity of the second adhesive layer 4 are ensured to satisfy the requirements.

Optionally, the elastic modulus of the material of the first adhesive layer 3 is greater than or equal to 0.3 GPa and less than or equal to 3 GPa; and/or the elastic modulus of the material of the second adhesive layer 4 is greater than or equal to 0.6 GPa and less than or equal to 6 GPa.

For example, under a condition that the elastic modulus of the material of the first adhesive layer 3 is equal to 0.3 GPa, the elastic modulus of the material of the second adhesive layer 4 may be equal to or greater than 0.6 GPa, e.g., 1 GPa, 2 Gpa, or 3 GPa; or under a condition that the elastic modulus of the material of the first adhesive layer 3 is equal to 3 GPa, the elastic modulus of the material of the second adhesive layer 4 may be equal to 6 GPa.

Optionally, in some embodiments, the second adhesive layer 4 comprises a first portion 41 and a second portion 42 that are connected to each other; the first portion 41 is disposed between the first adhesive layer 3 and the frame body 1; and the second portion 42 is disposed on the sides of the display panel 2 and the first adhesive layer 3 in the first direction X and is in contact with the frame body 1, the first direction X intersecting with the light-emission direction Y of the display panel 2.

It should be noted that the first portion 41 is provided between the first adhesive layer 3 and the frame body 1, and a high elastic modulus material is adopted to ensure the adhesive rigidity, provide a relatively good flatness, and ensure the sealability of adhering to the bottom plate 11 of the frame body 1. In addition, the second portion 42 is provided on the side of the display panel 2 and the first adhesive layer 3 in the first direction X, i.e., the second portion 42 is disposed corresponding to the side surface of the display panel 2 to achieve the seal encapsulation for the side surface of the display panel 2.

Optionally, the first adhesive layer 3 and the first portion 41 each are disposed between the display panel 2 and the bottom plate 11, and the second portion 42 is disposed on the sides of the display panel 2 and the first adhesive layer 3 in the first direction X and is in contact with the side plate 12. The first adhesive layer 3 is arranged close to the display panel 2 relative to the first portion 41, the first portion 41 may be directly in contact with the bottom plate 11, and the second portion 42 may be in contact with the side surface of the display panel 2 and the side surface of the first adhesive layer 3 in the first direction X.

Optionally, in some embodiments, referring to FIG. 2, the first adhesive layer 3 extends a preset distance in the first direction X toward the second portion 42, so that a portion of the first adhesive layer 3 is embedded in the second portion 42.

It should be noted that, in the present embodiment, by restricting the extension of the first adhesive layer 3 in the first direction X toward the second portion 42, the stress applied to the first adhesive layer 3 is transmitted toward the second portion 42, and the stress concentration point is transferred toward the direction where the second portion 42 is located, so that the stress applied to the weak portion (the inner side of the encapsulation adhesive 21) is reduced, and the overall strength is improved.

Optionally, in the first direction X, the first adhesive layer 3 comprises a first edge B1 close to the frame body 1, and the first direction X intersects with the light-emission direction Y of the display panel 2; the display panel 2 comprises an array layer 42, the encapsulation adhesive 21 is located on the side of the array layer 42 away from the first adhesive layer 3, and the array layer 42 comprises a second edge B2 close to the frame body 1; and in the light-emission direction Y of the display panel 2, the first edge B1 and the second edge B2 at least partially overlap.

In the present embodiment, the first adhesive layer 3 extends in the first direction X toward the second portion 42, and the first edge B1 of the extension portion may be flush with the second edge B2 of the array layer 42, so that the first adhesive layer 3 can withstand and release stress from the corresponding position of the array layer 42 to avoid damage of the array layer 42 resulting from stress concentration.

Optionally, referring to FIG. 2, in the light-emission direction Y of the display panel 2, the orthographic projection of the first edge B1 on the base plate coincides with the orthographic projection of the second edge B2 on the base plate, i.e., the first edge B1 may be flush with the second edge B2 of the array layer 42.

Optionally, the array layer 42 may include a driving circuit. For example, the array layer 42 may include a first conductive layer, a second conductive layer, and a third conductive layer that are disposed on the side of the substrate and are stacked. An insulation layer is arranged between any adjacent two of the conductive layers. In an example, a pixel driving circuit arranged on the array layer 42 includes a transistor and a storage capacitor. The transistor includes an active layer, a gate, a source, and a drain. The storage capacitor includes a first electrode plate and a second electrode plate. As an example, the gate and the first electrode plate may be located in the first conductive layer, the second electrode plate may be located in the second conductive layer, and the source and the drain may be located in the third conductive layer.

Optionally, the display panel 2 further comprises a light-emission functional layer 23 provided on the side of the array layer 42 away from the encapsulation adhesive 21; and optionally, the light-emission functional layer 23 comprises a first electrode layer, a light-emission layer, and a second electrode layer that are stacked and arranged in the direction away from the array layer 42.

Optionally, the light-emission layer includes one or more of an electron injection layer, an electron transport layer, a light-emission material layer, a hole blocking layer, an electron blocking layer, a hole transport layer, and a hole injection layer. It can be specifically selected according to the specific type of the light-emission layer and is not limited particularly. The electron injection layer, electron transport layer, and hole blocking layer may be arranged between the second electrode layer and the light-emission material layer. The electron blocking layer, hole transport layer, and hole injection layer may be disposed between the first electrode layer and the light-emission material layer.

The material of the first electrode layer is generally a material having a high work function to improve hole injection efficiency and may be gold (Au), platinum (Pt), titanium (Ti), silver (Ag), indium tin oxide (ITO, indium Tin Oxide), zinc tin oxide (IZO), or a transparent conductive polymer (e.g., polyaniline). For example, the first electrode layer may be made of an ITO-Ag-ITO composite material, which is not limited particularly.

It should be noted that the material of the second electrode layer may be any metal material of silver (Ag), aluminum (Al), lithium (Li), magnesium (Mg), ytterbium (Yb), calcium (Ca), or indium (In), and may further be an alloy of the aforementioned metal materials, such as magnesium-silver alloy (Mg/Ag), lithium-aluminum alloy (Li/Al), which is not limited in the present embodiment.

Optionally, referring to FIG. 2, in some embodiments, in the first direction X, the encapsulation adhesive 21 comprises a third edge B3 away from the frame body 1, the first adhesive layer 3 comprises a fourth edge B4 away from the frame body 1, and the second adhesive layer 4 comprises a fifth edge B5 away from the frame body 1 in the first direction X, and the first direction X intersects with the light-emission direction Y of the display panel 2; and in the light-emission direction Y of the display panel 2, the third edge B3, the fourth edge B4, and the fifth edge B5 at least partially overlap.

It should be noted that the third edge B3, the fourth edge B4, and the fifth edge B5 at least partially overlap in the light-emission direction Y of the display panel 2, which means that, in the light-emission direction Y of the display panel 2, the orthographic projections of the third edge B3, the fourth edge B4, and the fifth edge B5 on the base plate at least partially overlap to restrict the position and size of the first adhesive layer 3 and the second adhesive layer 4 in the first direction X, so that the narrow bezel requirement is achieved.

Optionally, in the light-emission direction Y of the display panel 2, the orthographic projections of the third edge B3, the fourth edge B4, and the fifth edge B5 on the substrate coincide completely.

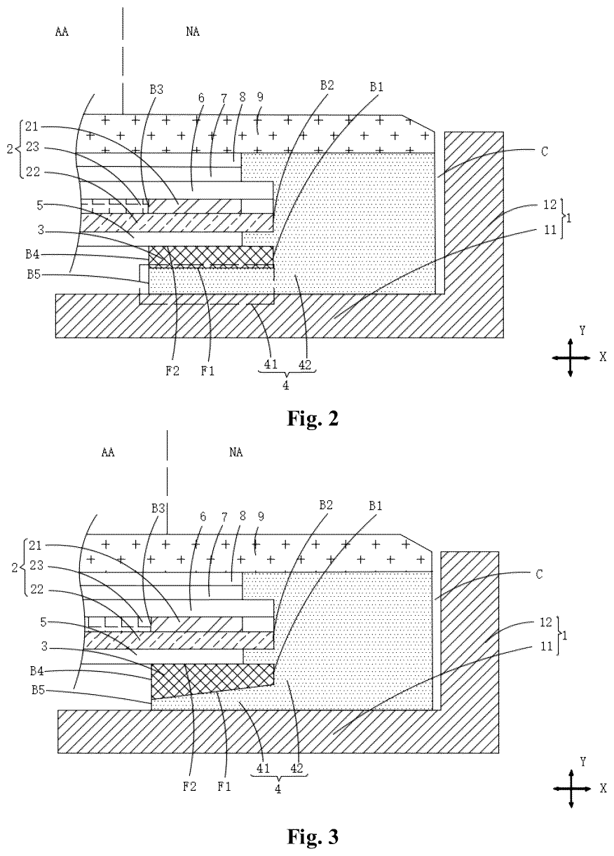

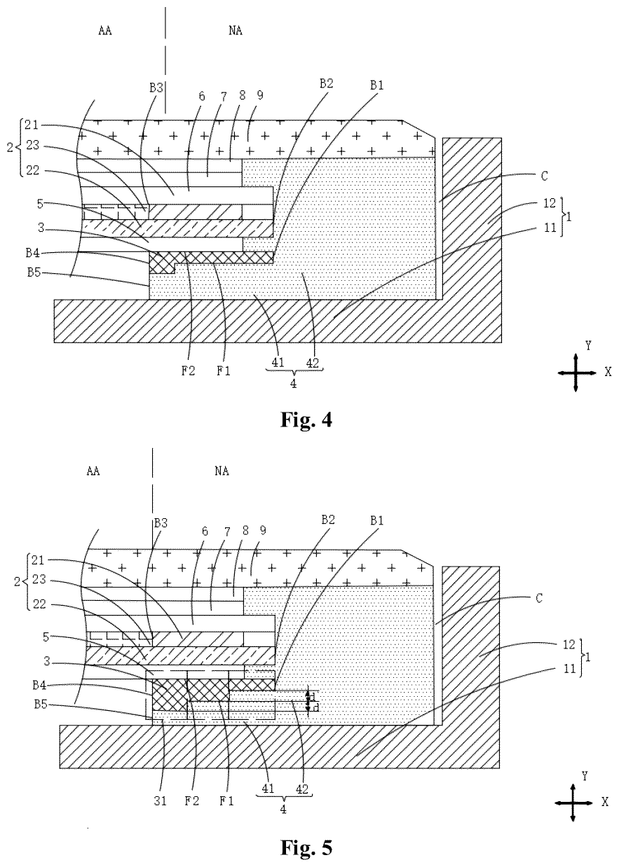

Referring to FIGS. 3 to 6, FIG. 3 shows a schematic cross-sectional view at A-A in FIG. 1 according to another embodiment of the present application; FIG. 4 shows a schematic cross-sectional view at A-A in FIG. 1 according to still another embodiment of the present application; and FIG. 5 shows a schematic cross-sectional view at A-A in FIG. 1 according to still another embodiment of the present application. Optionally, in some embodiments, the cross-sectional area of a first adhesive layer 3 has a decreasing trend in the direction from the display area AA toward the non-display area NA. The decreasing trend means that the cross-sectional area of the first adhesive layer 3 may decrease uniformly or in a stepwise way. Specifically, the thickness of the first adhesive layer 3 has a decreasing trend in the direction from the display area AA toward the non-display area NA. That is, the cross-sectional shape of the first adhesive layer 3 may be a trapezoid shape or a stepwise shape formed by a combination of a plurality of rectangles.

In the present embodiment, the cross-sectional area of the first adhesive layer 3 decreases in the direction from the display area AA toward the non-display area NA, i.e., in the direction from the display area AA toward the non-display area NA, the first adhesive layer 3 is formed as a structure with a wider front and a narrower back, the stress concentration point shifts to the narrow side, and the stress relief effect at the weak strength position is relatively good, so that the overall strength is improved.

Optionally, referring to FIG. 3, in the light-emission direction Y of the display panel 2, the first adhesive layer 3 comprises a first surface F1 and a second surface F2 opposite to each other, the first surface F1 is arranged away from the display panel 2 relative to the second surface F2, and the first surface F1 is inclined relative to the second surface F2.

It can be understood that, in the present embodiment, in the light-emission direction Y of the display panel 2, the cross-sectional shape of the first adhesive layer 3 may be trapezoidal, the first surface F1 and the second surface F2 correspond to two waists of the trapezoid respectively, and the length of the side of the trapezoid away from the frame body 1 is greater than the length of the side of the trapezoid facing the frame body 1, so that in the direction from the display area AA toward the non-display area NA, the cross-sectional area of the first adhesive layer 3 tends to decrease, and whether too large or too small, the inclination angle of the first surface F1 relative to the second surface F2 cannot work in shifting the stress concentration point of the first adhesive layer 3 to the narrow side. Optionally, the first surface F1 may be inclined at an angle of 30 to 60 degrees relative to the second surface F2.

Optionally, referring to FIGS. 4 to 6, in some embodiments, in the light-emission direction Y of the display panel 2, the first adhesive layer 3 comprises a first surface F1 and a second surface F2 opposite to each other, the first surface F1 is arranged away from the display panel 2 relative to the second surface F2, and the first surface F1 is a stepped surface.

It should be noted that the first surface F1 is a stepped surface, which means that, in the direction from the non-display area NA toward the display area AA, the first surface F1 may have a climbing trend and may be specifically a rectangular stepped surface or a trapezoidal stepped surface; correspondingly, in the direction from the display area AA toward the non-display area NA, the cross-sectional area of the first adhesive layer 3 may have a progressive decrease trend; for the same stepped surface, the cross-sectional area of the first adhesive layer 3 corresponding to each position may be equal, and the cross-sectional areas of the first adhesive layer 3 corresponding to different stepped surfaces are different; and specifically, in the direction from the display area AA toward the non-display area NA, the cross-sectional area of the first adhesive layer 3 corresponding to each stepped surface is arranged to gradually decrease.

Optionally, the second surface F2 may be a flat surface or a stepped surface, and is not particularly limited.

Optionally, referring to FIG. 5, in some embodiments, a first adhesive layer 3 comprises at least two sub-portions 31 connected to each other in a first direction X, the first direction X intersects with the light-emission direction Y of the display panel 2; and in the first direction X, the lengths of two adjacent sub-portions 31 are equal.

It can be understood that if the first surface F1 is a stepped surface, the corresponding sub-portions 31 each may form a different stepped surface, i.e., in the light-emission direction Y of the display panel 2, the thickness of each sub-section 31 is at least partially different. Optionally, in the direction from the display area AA toward the non-display area NA, the thickness of each sub-section 31 decreases gradually.

In the present embodiment, in the first direction X, the lengths of two adjacent sub-portions 31 are equal, so that in the direction from the display area AA toward the non-display area NA, the thickness of the first adhesive layer 3 changes uniformly to facilitate the preparation, ensure that the stress applied to the first adhesive layer 3 varies uniformly, and avoid the stress concentration problem.

Optionally, referring to FIG. 4, in some embodiments, in the direction from the display area AA toward the non-display area NA, the lengths of the sub-portions 31 are gradually increased, i.e., the closer to the frame body 1, the greater the length of the sub-portion 31 in the first direction X, so that the stress is gradually weakened, the stress concentration point of the first adhesive layer 3 is transferred to the sub-portion 31 close to the frame body 1, the stress relief effect at the weak strength position is better, and the overall strength is improved.

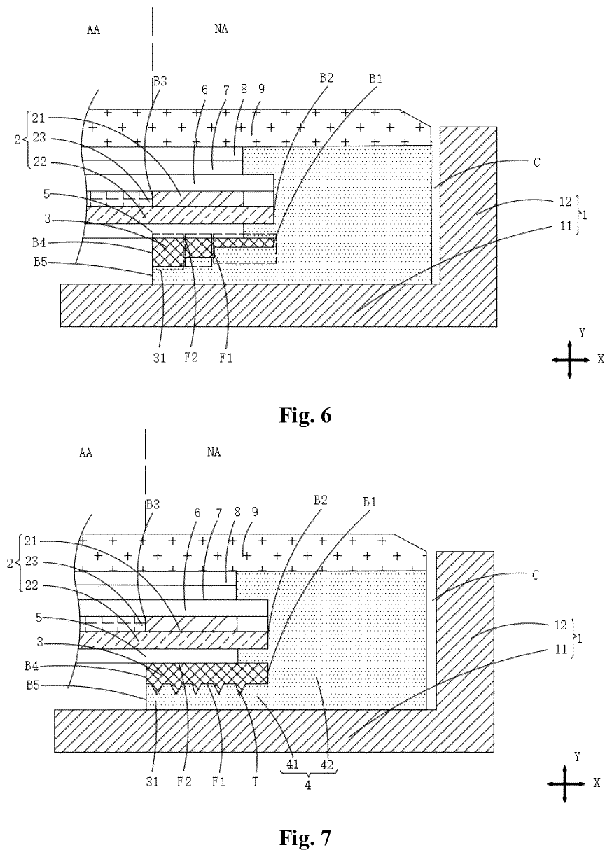

Additionally or alternatively, as shown in FIG. 6, the lengths of some sub-portions 31 in the first direction X may be equal, and the lengths of others in the first direction X may be unequal.

Optionally, in the direction from the display area AA toward the non-display area NA, the length of one, close to the frame body 1, of two adjacent sub-portions 31 is greater than or equal to twice the length of the other sub-portion 31.

Optionally, referring to FIG. 5, in some embodiments, a first adhesive layer 3 comprises at least three sub-portions 31 connected to each other in a first direction X, the first direction intersects the light-emission direction Y of the display panel 2, and the difference between the thicknesses d of any adjacent two of the sub-sections 31 is equal.

It can be understood that, in the light-emission direction Y of the display panel 2, the thickness of the sub-portion 31 may affect the stress release effect at the corresponding position of the first adhesive layer 3; the greater the thickness, the better the corresponding release effect; and the difference between the thicknesses of any adjacent two of the sub-portions 31 is equal, so that the stress release effect of each sub-portion 31 is uniformly changed to avoid an abrupt change leading to excessive stress applied on the first adhesive layer 3 at a certain position and ensure that the overall stress release effect of the first adhesive layer 3 satisfies the requirements.

It should be noted that the number of the sub-sections 31 in the first adhesive layer 3 is not particularly limited and may be selected according to the size of the display panel 2 and the size of the first adhesive layer 3. For example, the first adhesive layer 3 may include three, four, five or more sub-sections 31 connected to each other.

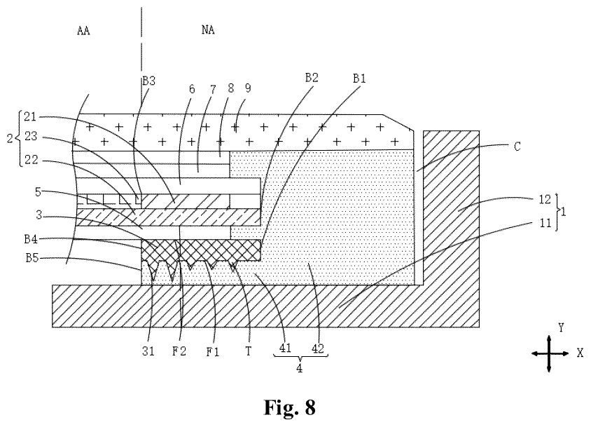

Referring to FIGS. 7 and 8, FIG. 7 shows a schematic cross-sectional view at A-A in FIG. 1 according to still another embodiment of the present application; and FIG. 8 shows a schematic cross-sectional view at A-A in FIG. 1 according to still another embodiment of the present application. Optionally, in some embodiments, in the light-emission direction Y of the display panel 2, a first adhesive layer 3 comprises a first surface F1 and a second surface F2 opposite to each other; the first surface F1 is arranged away from the display panel 2 relative to the second surface F2; the first surface F1 is provided with protrusion portions T protruding toward the second adhesive layer 4, and the protrusion portions T are embedded in the second adhesive layer 4.

It can be understood that by providing protrusion portions T embedded in the second adhesive layer 4 on the first surface F1, the bonding force between the first adhesive layer 3 and the second adhesive layer 4 can be increased to prevent the first adhesive layer 3 and the second adhesive layer 4 from delaminating, and the reliability is improved. The distance over which the protrusion portions T are embedded in the second adhesive layer 4 should not be too large; if the distance is too large, the protrusion portions T may penetrate the second adhesive layer 4, and the sealability is affected; if the distance is too small, the protrusion portions T may have a limited function, the bonding force between the first adhesive layer 3 and the second adhesive layer 4 cannot be effectively increased; and it can be specifically selected according to actual situations.

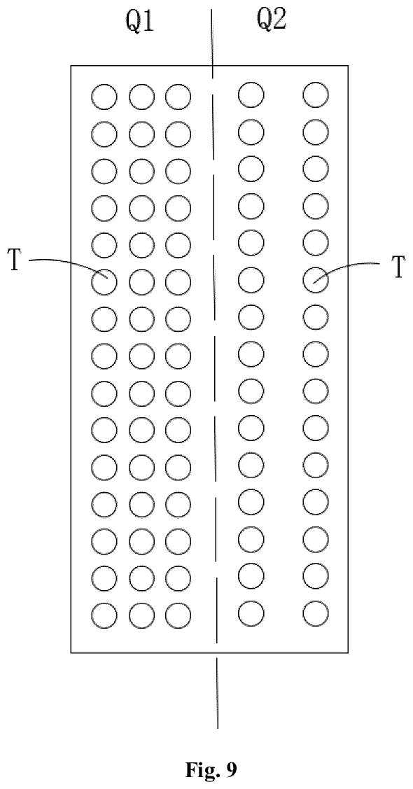

Referring to FIG. 9, FIG. 9 shows a schematic structural diagram of a first adhesive layer 3 provided in an embodiment of the present application. Optionally, in some embodiments, a first surface F1 comprises a first area Q1 and a second area Q2, the first area Q1 is arranged away from the frame body 1 relative to the second area Q2 in a first direction X, and the first direction X intersects with the light-emission direction Y of the display panel 2; and the distribution density of the protrusion portions T in the first area Q1 is greater than or equal to the distribution density of the protrusion portions T in the second area Q2.

It can be understood that the greater the number of the protrusion portions T are disposed, the greater the contact area between the protrusion portions T and the second adhesive layer 4 in the corresponding area, the greater the bonding force between the protrusion portions T and the second adhesive layer 4, the less easy the separation between the protrusion portions T and the second adhesive layer 4, and the better the stress release effect. In the present embodiment, the first area Q1 is provided away from the frame body 1 relative to the second area Q2, i.e., the first area Q1 is closer to the inner edge of the encapsulation adhesive 21 relative to the second area Q2, and the distribution density of the protrusion portions T in the first area Q1 can be greater than that in the second area Q2 to enhance the ability of the first area Q1 to adsorb and release the stress of the portion, corresponding to the encapsulation adhesive 21, of the display panel 2, reduce the stress on the inner side of the encapsulation adhesive 21, and improve the overall strength.

Furthermore, the distribution density of the protrusion portions T in the first area Q1 may further be equal to the distribution density of the protrusion portions T in the second area Q2, so that the protrusion portions T are uniformly arranged, and the consistency of the connection effect is ensured throughout the interface between the first adhesive layer 3 and the second adhesive layer 4.

It should be noted that, to make the distribution density of the protrusion portions T in the first area Q1 greater than or equal to the distribution density of the protrusion portions T in the second area Q2, by adjusting the number of the protrusion portions T in the first area Q1 greater than or equal to the number of the protrusion portions T in the second area Q2, the distance between adjacent protrusion portions T is adjusted to adjust the distribution density of the protrusion portions T; or the distribution density of the protrusion portions T can be adjusted by adjusting the shape and size of the protrusion portions T in the first area Q1 and the second area Q2. For example, in the light-emission direction Y of the display panel 2, the orthographic projection areas of the protrusion portions T of the first area Q1 and the second area Q2 on the frame body 1 can be adjusted to correspondingly adjust the distribution density of the protrusion portions T.

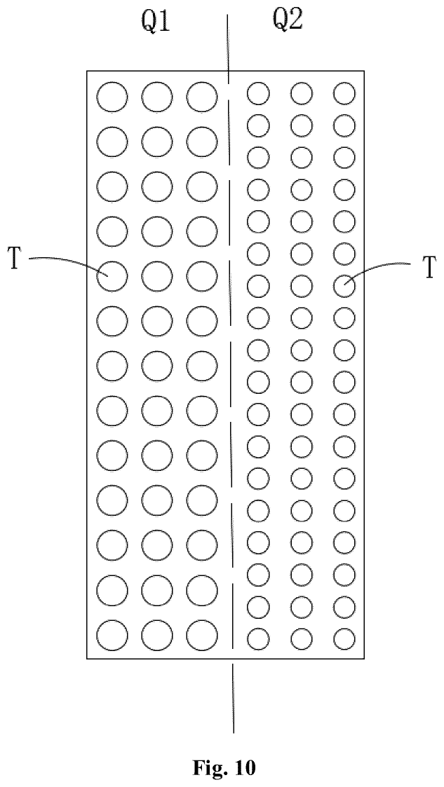

Referring to FIG. 10, FIG. 10 shows a schematic structural diagram of a first adhesive layer 3 provided in another embodiment of the present application. Optionally, in the light-emission direction Y of the display panel 2, the orthographic projection area of the protrusion portion T in the first area Q1 on the frame body 1 is larger than the orthographic projection area of the protrusion portion T in the second area Q2 on the frame body 1.

It can be understood that the greater the orthographic projection area of protrusion portion T on the frame body 1 in the first area Q1, and the greater the contact area between the second layer of adhesive 4 and the portion, embedded in the second adhesive layer 4, of the corresponding protrusion portion T; and by increasing the orthographic projection area of the protrusion portion T in the first area Q1 on the frame body 1, the distance between adjacent protrusion portions T is reduced to increase the distribution density of the projections T in the first area Q1.

Optionally, referring to FIG. 8, in some embodiments, in the light-emission direction Y of the display panel 2, the protrusion height of the protrusion portions T in the first area Q1 is greater than or equal to the protrusion height of the protrusion portions T in the second area Q2.

It can be understood that the higher the protrusion height of the protrusion portions T is, the greater the bonding force between the corresponding protrusion portion T and the second adhesive layer 4 is, the less easy the separation between the corresponding protrusion portion T and the second adhesive layer 4 is, and the better the stress release effect is. In the present embodiment, in the light-emission direction Y of the display panel 2, the protrusion height of the protrusion portions T in the first area Q1 is greater than the protrusion height of the protrusion portions T in the second area Q2 to enhance the ability of the first area Q1 to adsorb and release the stress of the portion, corresponding to the encapsulation adhesive 21, of the display panel 2, reduce the stress on the inner side of the encapsulation adhesive 21, and improve the overall strength.

Optionally, in some embodiments, in the light-emission direction Y of the display panel 2, the cross-sectional shape of the protrusion portion T is at least one of a polygon and a semicircle. For example, the cross-sectional shape of the protrusion portion T may be a rectangle, a triangle, a semicircle, and a trapezoid. Optionally, for facilitating the protrusion portion T to be embedded in the second adhesive layer 4, in the light-emission direction Y of the display panel 2, the protrusion portion T can be provided in a widened manner to facilitate insertion of the tip of the protrusion portion T into the second glue layer 4.

Optionally, in the light-emission direction Y of the display panel 2, the shape of the orthographic projection of the protrusion portion T on the frame body 1 is at least one of a polygon and a circle, and in combination with the above-mentioned cross-sectional shape of the protrusion portion T in the light-emission direction Y of the display panel 2, the protrusion portion T as a whole can have a structure such as a cylinder, a cone, a rectangular cylinder, a prism, or a hemisphere, which can be specifically selected according to actual requirements and is not particularly limited.

Optionally, the display apparatus further comprises a composite adhesive layer 5 at least partially arranged between the display panel 2 and the first adhesive layer 3, and the first adhesive layer 3 is in contact with the composite adhesive layer 5. In the present embodiment, the composite adhesive layer 5 is disposed between the display panel 2 and the first adhesive layer 3 to provide adhesion and certain cushioning functions. Optionally, the composite adhesive layer 5 comprises a first bonding layer, a foam layer, and a second bonding layer that are stacked.

Optionally, the display apparatus further comprises film layer components, such as an encapsulation layer 6, a polaroid 7, an optical adhesive 8, and a cover plate 9, which are arranged on the light-emission side of the display panel 2.

The optical adhesive 8 can use an optically clear adhesive (OCA) specifically, OCA is a double-sided adhesive tape without a base material obtained by making an optical acrylic adhesive into a base material and attaching a release film to the upper and lower bottom layers separately, and the adhesive layer of OCA has uniform thickness, high flatness, strong adhesion, and high bonding strength. Alternatively, the optical adhesive 8 can use an adhesive layer made of other materials, such as a double-sided adhesive.

It can be understood that the cover plate 9 is a film layer made of a material such as glass with a high light transmittance to protect the display panel 2. Specifically, the cover plate 9 can be made of a rigid material with a relatively low cost; or the cover plate 9 can be made of a flexible material, thereby being foldable and applicable to a flexible and foldable display module, i.e., specifically, the cover plate 9 can be made of a transparent, soft, and foldable material such as an ultrathin glass (UTG), colorless polyimide (CPI), or polyethylene terephthalate (PET) to achieve the bendable folding of the cover plate 9, which facilitates applying it to the foldable display panel 2.

It can be understood that the encapsulation layer 6 is for encapsulating and protecting the display panel 2.

Optionally, the encapsulation layer 6 comprises a first encapsulation layer, the material of the first encapsulation layer comprises an inorganic material, the inorganic material can be materials such as silicon nitride, silicon oxide, or silicon oxynitride and can adopt a chemical vapor deposition (CVD) process specifically.

Optionally, the encapsulation layer 6 further comprises a second encapsulation layer on the side of the first encapsulation layer away from the display panel 2, the material of the second encapsulation layer comprising an organic material. The organic material may be made of a resin or a high molecular organic material and may be specifically formed by an inkjet printing (IJP) process.

Optionally, the encapsulation layer 6 further comprises a third encapsulation layer disposed on the side of the second encapsulation layer away from the display panel 2, and the material of the third encapsulation layer comprises an inorganic material; the inorganic encapsulation layer additionally disposed outside the organic encapsulation layer can further improve the encapsulation effect of the encapsulation layer 6. In the present embodiment, the material of the third encapsulation layer may be the same as or different from the material of the first encapsulation layer, which is not particularly limited.

Optionally, the material of the first encapsulation layer is the same as the material of the third encapsulation layer, so that the first encapsulation layer and the third encapsulation layer can be prepared by the same equipment, and the preparation process of the display apparatus can be simplified.

The display apparatus provided by the embodiment of the present application may be applied to a mobile phone, and may also be applied to any electronic product with a display function, including but not limited to the following categories: televisions, notebook computers, desktop monitors, tablet computers, digital cameras, smart rings, smart glasses, in-vehicle displays, medical equipment, industrial control equipment, touch interactive terminals, etc., which are not particularly limited in this embodiment of the present application.

The above are only specific implementations of the present application, those skilled in the art can clearly understand that the specific working processes of the above-described systems, modules and units can be referred to the corresponding processes in the foregoing method embodiments for the convenience and brevity of the description, which is not repeated here. It should be understood that, the protection scope of this application is not limited to this, and any person skilled in the art can readily conceive of various equivalent modifications or replacements within the technical scope disclosed in this application, and these modifications or replacements should all be covered within the scope of protection of this application.

It should also be noted that, according to the exemplary embodiments described in the present application, some methods or systems are described based on a series of steps or apparatus. However, the present application is not limited to the above order of the steps, that is, the steps may be executed in the order described in the embodiments or in orders different from that in the embodiments, or several steps may be executed at the same time.

What is claimed is:

1. A display apparatus, comprising:
a frame body having an accommodation groove;
a display panel disposed in the accommodation groove and comprising a display area and a non-display area adjacent to the display area, wherein the display panel comprises an encapsulation adhesive disposed in the non-display area, and the display panel further comprises a light-emission surface and a back surface opposite to the light-emission surface;
a first adhesive layer provided between the back surface of the display panel and the frame body, wherein in a light-emission direction of the display panel, the first adhesive layer at least partially overlap the encapsulation adhesive; and
a second adhesive layer disposed at least partially between the first adhesive layer and the frame body in the light-emission direction of the display panel, an elastic modulus of a material of the second adhesive layer being greater than an elastic modulus of a material of the first adhesive layer.

2. The display apparatus according to claim 1, wherein a ratio between the elastic modulus of the material of the second adhesive layer and the elastic modulus of the material of the first adhesive layer is greater than or equal to 2:1.

3. The display apparatus according to claim 1, wherein the elastic modulus of the material of the first adhesive layer is greater than or equal to 0.3 GPa and less than or equal to 3 GPa; and/or
the elastic modulus of the material of the second adhesive layer is greater than or equal to 0.6 GPa and less than or equal to 6 GPa.

4. The display apparatus according to claim 1, wherein the material of the first adhesive layer comprises a one-component epoxy resin adhesive; and/or,
the material of the second adhesive layer comprises a one-component epoxy resin adhesive.

5. The display apparatus according to claim 1, wherein the second adhesive layer comprises a first portion and a second portion that are connected to each other; and
the first portion is disposed between the first adhesive layer and the frame body, the second portion is disposed on sides of the display panel and the first adhesive layer in a first direction and is in contact with the frame body, and the first direction intersects with the light-emission direction of the display panel.

6. The display apparatus according to claim 5, wherein the frame body comprises a bottom plate and a side plate connected to the bottom plate, and the accommodation groove is enclosed and formed by the bottom plate and the side plate; and
the first adhesive layer and the first portion each are disposed between the display panel and the bottom plate, and the second portion is disposed on the sides of the display panel and the first adhesive layer in the first direction and is in contact with the side plate.

7. The display apparatus according to claim 5, wherein the first adhesive layer extends for a preset distance toward the second portion in the first direction to embed part of the first adhesive layer in the second portion.

8. The display apparatus according to claim 1, wherein in a first direction, the first adhesive layer comprises a first edge close to the frame body, the first direction intersecting with the light-emission direction of the display panel;
the display panel further comprises an array layer, the encapsulation adhesive is located at a side of the array layer away from the first adhesive layer, and the array layer comprises a second edge close to the frame body; and
the first edge at least partially overlaps the second edge in the light-emission direction of the display panel.

9. The display apparatus according to claim 1, wherein in a first direction, the encapsulation adhesive comprises a third edge away from the frame body, the first adhesive layer comprises a fourth edge away from the frame body, the second adhesive layer comprises a fifth edge away from the frame body, and the first direction intersects with the light-emission direction of the display panel; and
the third edge, the fourth edge, and the fifth edge at least partially overlap in the light-emission direction of the display panel.

10. The display apparatus according to claim 1, wherein in a direction from the display area toward the non-display area, a cross-sectional area of the first adhesive layer tends to decrease.

11. The display apparatus according to claim 10, wherein in the light-emission direction of the display panel, the first adhesive layer comprises a first surface and a second surface that are opposite to each other, and the first surface is disposed away from the display panel relative to the second surface; and
the first surface is inclined relative to the second surface.

12. The display apparatus according to claim 10, wherein in the light-emission direction of the display panel, the first adhesive layer comprises a first surface and a second surface that are opposite to each other, and the first surface is disposed away from the display panel relative to the second surface; and
the first surface is a stepped surface.

13. The display apparatus according to claim 10, wherein in a first direction, the first adhesive layer comprises at least two sub-portions connected to each other, and the first direction intersects with the light-emission direction of the display panel; and
in the first direction, lengths of adjacent two of the sub-sections are equal, or in the direction from the display area toward the non-display area, lengths of the sub-portions gradually increase.

14. The display apparatus according to claim 10, wherein in a first direction, the first adhesive layer comprises at least three sub-portions connected to one another, and the first direction intersects with the light-emission direction of the display panel; and
a difference between thicknesses of any adjacent two of the sub-portions is equal.

15. The display apparatus according to claim 1, wherein in the light-emission direction of the display panel, the first adhesive layer comprises a first surface and a second surface that are opposite to each other, and the first surface is disposed away from the display panel relative to the second surface; and
the first surface is provided with protrusion portions protruding toward the second adhesive layer, and the protrusion portions are embedded in the second adhesive layer.

16. The display apparatus according to claim 15, wherein the first surface comprises a first area and a second area, the first area is disposed away from the frame body relative to the second area in a first direction, and the first direction intersects with the light-emission direction of the display panel; and
a distribution density of the protrusion portions in the first area is greater than or equal to a distribution density of the protrusion portions in the second area.

17. The display apparatus according to claim 16, wherein in the light-emission direction of the display panel, a protrusion height of the protrusion portions in the first area is greater than or equal to a protrusion height of the protrusion portions in the second area.

18. The display apparatus according to claim 16, wherein in the light-emission direction of the display panel, an orthographic projection area of the protrusion portions in the first area on the frame body is larger than an orthographic projection area of the protrusion portions in the second area on the frame body.

19. The display apparatus according to claim 15, wherein in the light-emission direction of the display panel, cross-sectional shapes of the protrusion portions are at least one of a polygon and a semicircle.

20. The display apparatus according to claim 15, wherein in the light-emission direction of the display panel, orthographic shapes of the protrusion portions on the frame body are at least one of a polygon and a circle.

21. The display apparatus according to claim 1, further comprising a composite adhesive layer at least partially disposed between the display panel and the first adhesive layer, the first adhesive layer being in contact with the composite adhesive layer.
